(19) United States
(12) Patent Application Publication
(10) Pub. No.: US 2021/0307215 A1
(43) Pub. Date: Sep. 30, 2021

(54) SHIELDING IMPROVEMENT FOR A DATA STORAGE DEVICE

(71) Applicant: Western Digital Technologies, Inc., San Jose, CA (US)

(72) Inventors: Daniel OH, San Jose, CA (US); Antonio Ciccomancini SCOGNA, San Jose, CA (US); Albert John WALLASH, Morgan Hill, CA (US)

(21) Appl. No.: 16/834,403

(22) Filed: Mar. 30, 2020

(51) Int. Cl. H05K 9/00; H01R 4/56; H01R 4/58; G11B 33/12; G11B 33/14

(52) U.S. Cl. CPC H05K 9/002; H01R 4/56; G11B 33/1493; G11B 33/122; H01R 4/58

(57) ABSTRACT

The present disclosure generally relates to reducing radio frequency (RF) interference in data storage devices, including both hard disk drives (HDDs) and solid state drives (SSDs). RF signals penetrate data storage devices through gaps in the drive enclosure. By providing a conductive connection between a top plate and the base body, a reduction in RF signals penetrating into the interior of a data storage device such as an HDD or SSD and thus, RF interference is reduced.

### BACKGROUND OF THE DISCLOSURE

### Field of the Disclosure

Embodiments of the present disclosure generally relate to reducing radio frequency (RF) interference.

### Description of the Related Art

RF interference in drives, such as hard disk drives (HDDs) and solid state drives (SSDs) can be an issue that leads to device failure. Many drives' high data rate frequencies occupy the same RF signal frequency bands of wireless communication networks. The RF signals interfere with the low-amplitude read signal of the data. The RF signals penetrate the drive through open spaces in the drive enclosure. The RF signals then interfere with reading the data and hence, is RF interference.

RF interference leads to errors in data delivered from the drives to the host device. A certain amount of errors is to be expected, but in a general case, most end users will not tolerate more than 10 percent degradation of data throughput at the frequency of operation of the drive. A degradation of data throughput is caused by data errors. The more data errors that are present, the lower the data throughput.

The drives tend to operate at frequencies of between about 200 MHz and about 1000 MHz. RF interference can really become an issue at frequencies above 900 MHz, and in particular, above 925 MHz. In fact, above 950 MHz, data errors can be so significant that the data throughput can decrease to 60 percent or less, which is unacceptable.

Therefore, what is needed is a mechanism to reduce RF interference in drives.

### SUMMARY OF THE DISCLOSURE

The present disclosure generally relates to reducing radio frequency (RF) interference in data storage devices, including both hard disk drives (HDDs) and solid state drives (SSDs). RF signals penetrate data storage devices through gaps in the drive enclosure. By providing a conductive connection between a top plate and the base body, a reduction in RF signals penetrating into the interior of a data storage device such as an HDD or SSD and thus, RF interference is reduced.

In one embodiment, a data storage device comprises: a base body; a top plate; and a plurality of connector elements, wherein: a first connector element of the plurality of connector elements couples a first corner area of the top plate to a corresponding first corner area of the base body; a second connector element of the plurality of connector elements couples a second corner area of the top plate to a corresponding second corner area of the base body; a third connector element of the plurality of connector elements couples a third corner area of the top plate to a corresponding third corner area of the base body; a fourth connector element of the plurality of connector elements couples a fourth corner area of the top plate to a corresponding fourth corner area of the base body; a fifth connector element of the plurality of connector elements couples a fifth area of the top plate to a corresponding fifth area of the base body, wherein the fifth area is disposed between the second area and the third area; and a sixth connector element of the plurality of connector elements couples a sixth area of the top plate to a corresponding sixth area of the base body, wherein the sixth area is disposed between the first area and the fourth area, wherein at least one of the fifth connector element and the sixth connector element is electrically conductive.

In another embodiment, a data storage device comprises: a base body having a first base body edge, a second base body edge, a third base body edge and a fourth base body edge, wherein the first base body edge and the third base body edge are parallel and of equal length, wherein the second base body edge and the fourth base body edge are parallel and of equal length, and wherein the first base body edge is shorter than the second base body edge; a top plate having a first top plate edge, a second top plate edge, a third top plate edge and a fourth top plate edge, wherein the first top plate edge and the third top plate edge are parallel and of equal length, wherein the second top plate edge and the fourth top plate edge are parallel and of equal length, and wherein the first top plate edge is shorter than the second top plate edge; and a plurality of connector elements, wherein: a first connector element of the plurality of connector elements couples the second base body edge to the second top plate edge; and a second connector element of the plurality of connector elements couples the fourth base body edge to the fourth top plate edge, wherein at least one of the first connector element and the second connector element is electrically conductive.

In another embodiment, a data storage device comprises: a base body; a top plate; and means to reduce radio frequency interference, wherein the means to reduce radio frequency interference is disposed between at locations disposed away from corner areas of the base body and the top plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a disk drive embodying various embodiments of this disclosure.

FIG. 2 is a graph illustrating the problem with RF interference for drives.

FIGS. 3A, 3B, and 3C are schematic illustrations of a drives comprising the disk drive of FIG. 1.

FIGS. 4A, 4B, and 4C are schematic illustrations of drives with an added component to reduce RF interference according to various embodiments.

FIGS. 5A, 5B, and 5C are schematic illustrations of drives with an added component to reduce RF interference according to various embodiments.

FIGS. 6A, 6B, 6C, and 6D are schematic illustrations of drives with an added component to reduce RF interference according to various embodiments.

FIG. 7 is a schematic illustration of a drive with an added component to reduce RF interference according to various embodiments.

FIGS. 8A and 8B are graphs illustrating the benefits of reducing RF interference.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to reducing radio frequency (RF) interference in data storage devices, including both hard disk drives (HDDs) and solid state drives (SSDs). RF signals penetrate data storage devices through gaps in the drive enclosure. By providing a conductive connection between a top plate and the base body, a reduction in RF signals penetrating into the interior of a data storage device such as an HDD or SSD and thus, RF interference is reduced. While the various embodiments will now be described using HDDs or SSDs as examples, the disclosure is not limited to these types of storage devices. In some embodiments, the data storage device may be a magnetic tape-based data storage device, for example.

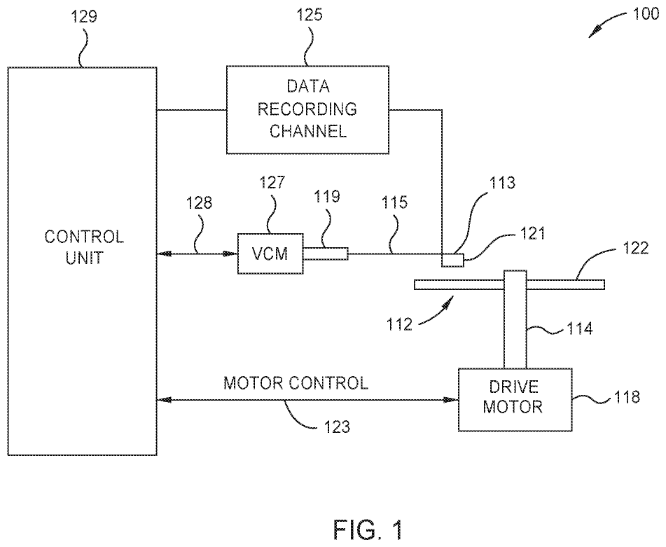

FIG. 1 illustrates a data storage device in the form of a disk drive 100 embodying various embodiments of this disclosure. As shown, at least one rotatable magnetic media 112 is supported on a spindle 114 and rotated by a disk drive motor 118. The magnetic recording on each disk is in the form of any suitable patterns of data tracks, such as annular patterns of concentric data tracks (not shown) on the magnetic media 112.

At least one slider 113 is positioned near the magnetic media 112, each slider 113 supporting one or more magnetic head assemblies 121. As the magnetic media 112 rotates, the slider 113 moves radially in and out over the media surface 122 so that the magnetic head assembly 121 may access different tracks of the magnetic media 112 where desired data are written. Each slider 113 is attached to an actuator arm 119 by way of a suspension 115. The suspension 115 provides a slight spring force which biases the slider 113 toward the media surface 122. Each actuator arm 119 is attached to an actuator means 127. The actuator means 127 as shown in FIG. 1 may be a voice coil motor (VCM). The VCM includes a coil movable within a fixed magnetic field, the direction, and speed of the coil movements being controlled by the motor current signals supplied by a control unit or controller 129.

During operation of the disk drive 100, the rotation of the magnetic media 112 generates an air bearing between the slider 113 and the media surface 122 which exerts an upward force or lift on the slider 113. The air bearing thus counter-balances the slight spring force of suspension 115 and supports slider 113 off and slightly above the media 112 surface by a small, substantially constant spacing during normal operation. The magnetic field generated from the magnetic head assembly 121 magnetizes the data bits in the media 112.

The various components of the disk drive 100 are controlled in operation by control signals generated by a control unit or controller 129, such as access control signals and internal clock signals. Typically, the control unit or controller 129 comprises logic control circuits, storage means, and a microprocessor. The control unit or controller 129 generates control signals to control various system operations, such as drive motor control signals on line 123 and head position and seek control signals on line 128. The control signals on line 128 provide the desired current profiles to optimally move and position slider 113 to the desired data track on media 112. Write and read signals are communicated to and from write and read heads on the assembly 121 by way of recording channel 125.

The above description of a typical magnetic disk storage system and the accompanying illustration of FIG. 1 are for representation purposes only. It should be apparent that disk storage systems may contain a large number of disks and actuators, and each actuator may support several sliders.

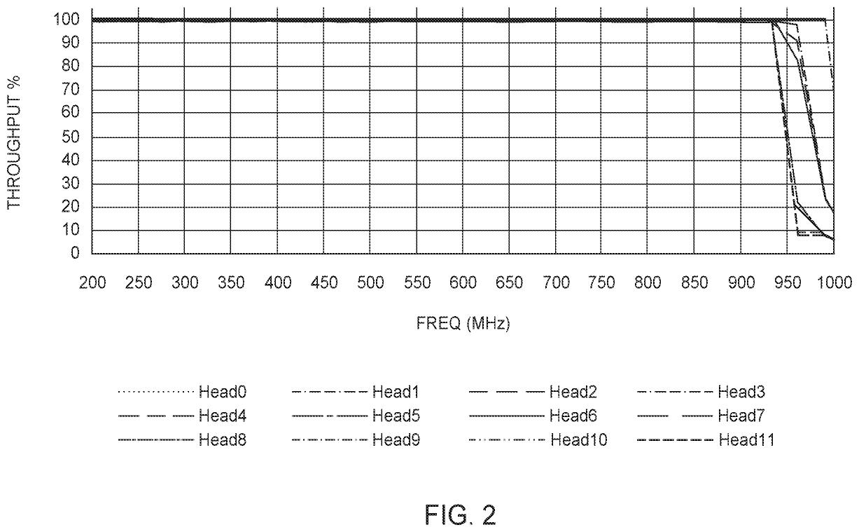

FIG. 2 is a graph illustrating the problem with radio frequency (RF) interference for drives, which in this example is an HDD with several magnetic heads. The x-axis comprises frequencies in MHz ranging from 200 MHz to 1000 MHz. The frequency range listed is not intended to be limiting, but to provide an example of the RF interference for drives. The y-axis comprises the RF signal throughput from 0% to 100%, where 0% throughput indicates about 100% RF interference and 100% throughput indicates about 0% RF interference. For each head, such as Head0, a curve is generated for each frequency and throughput percentage combination.

The drive is exposed to various strengths of frequencies (i.e., the x-axis). Generally, the industry accepted threshold for a range of frequencies, such as 200 MHz to 1000 MHz, is 90% throughput. If a frequency causes a head, such as the magnetic head 121 of FIG. 1, to decrease below 90%, the drive may fail the quality assurance test. Typically, higher frequencies, such as greater than 930 MHz, may cause a decrease in the throughput percentage of a magnetic head.

RF interference may be caused by a variety of devices, such as, but not limited to, cell phones and microwaves. For example, the RF interference generated by a cell phone may be enough to decrease the throughput percentage to below 90%. Furthermore, potential sources of RF interference include: a concentration of electronic devices in a spectrum, a compromised connection of electronic devices, a poor enclosure design with a low absorption loss, and any other potential cause for RF interference not listed. Minimization techniques, such as shielding and filtering, may reduce the intensity of the RF interference. However, the remaining RF interference may still be a concern and may cause bit errors, data loss, and similar results not stated.

In FIG. 2, 12 magnetic heads, Head0-Head11, are graphed. Each magnetic head is exposed to varying levels of radio frequencies. The throughput percentage of each of the magnetic heads, excluding Head9, decreases to below 90% at or above about 960 MHz. The throughput percentage of Head9 decreases to below 90% at about 990 MHz. Each head may fail a quality assurance test that requires the magnetic head to have a throughput percentage above 90% for the entire radio frequency range of 200 MHz to 1000 MHz.

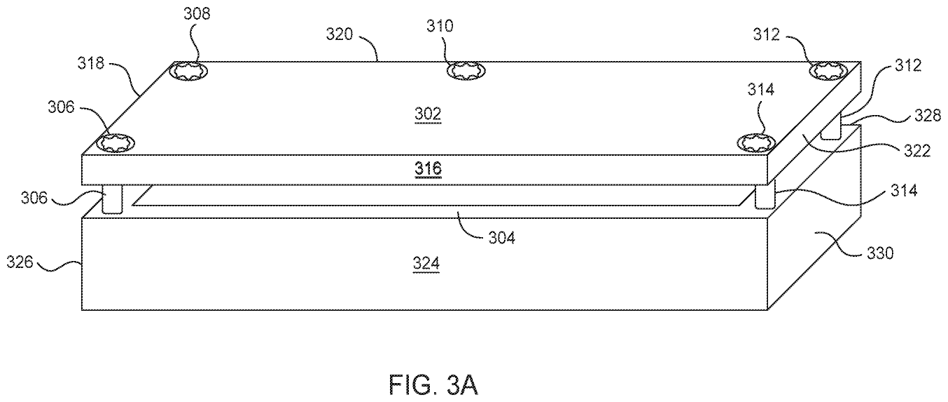

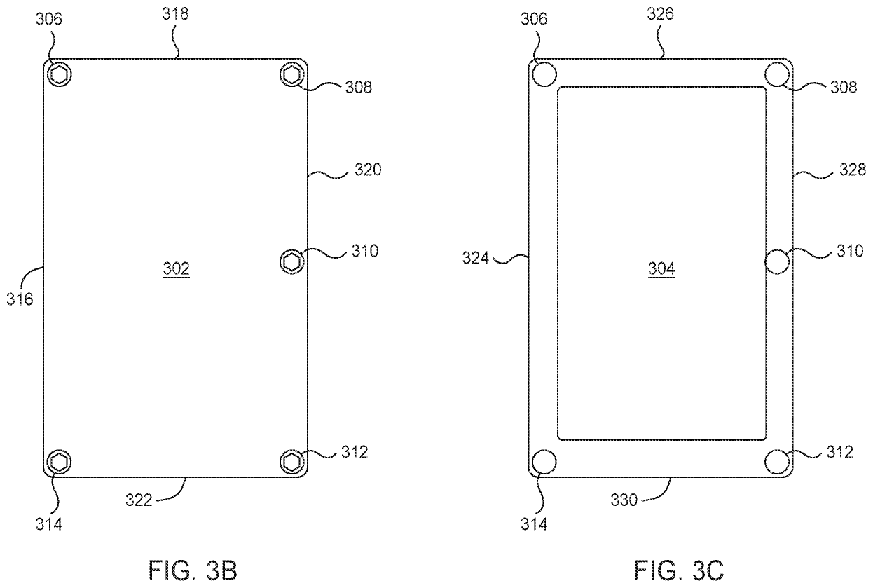

FIGS. 3A, 3B, and 3C are schematic illustrations of a data storage device. The data storage device, such as a hard disk drive (HDD), solid state drive (SSD), or the like, comprises a base body 304, which may be referred to as a base plate for exemplary purposes herein, and a top plate 302, which may be referred to as a cover plate for exemplary purposes herein. The base plate 304 and the cover plate 302 are coupled to each other through a first connector element 306 of a plurality of connector elements in a first corner area, a second connector element 308 of a plurality of connector elements in a second corner area, a third connector element 312 of a plurality of connector elements in a third corner area, a fourth connector element 314 of a plurality of connector elements in a fourth corner area, and a fifth connector element 310 of a plurality of connector elements in a fifth area disposed between the second corner area and the third corner area. In one embodiment, the fifth connector element 310 may be electrically conductive. In another embodiment, the fifth connector element 310 and one or more connector elements, such as connector elements 306, 308, 312, and 314, may be electrically conductive.

The storage device comprises a first base body edge 326 that is of equal length and parallel to a first top plate edge 318, a third base body edge 330, and a third top plate edge 322. The storage device further comprises a second base body edge 328 that is of equal length and parallel to a second top plate edge 320, a fourth base body edge 324, and a fourth top plate edge 316. Furthermore, the first and third top plate edges 318, 322 and the first and third base body edges 326, 330 are of a shorter length than the second and fourth top plate edges 320, 316 and the second and fourth base body edges 328, 324. Furthermore, the top plate 302 and the base body 304 are parallel and have equal length and width. A formed-in-place gasket (FIPG), which is a non-conductive adhesive designed to prevent fluid leakage as well as dust or air intrusion, is located in the slot between the top plate 302 and the base body 304 of the storage device.

The first corner area of a first connector element 306 is the intersection of the fourth and first top plate edges 316, 318 and of the intersection of the fourth and first base body edges 324, 326. The second corner area of a second connector element 308 is the intersection of the first and second top plate edges 318, 320 and of the intersection of the first and second base body edges 326, 328. The third corner area of a third connector element 312 is the intersection of the second and third top plate edges 320, 322 and of the intersection of the second and third base body edges 328, 330. The fourth corner area of a fourth connector element 314 is the intersection of the third and fourth top plate edges 322, 316 and of the intersection of the third and fourth base body edges 322, 316.

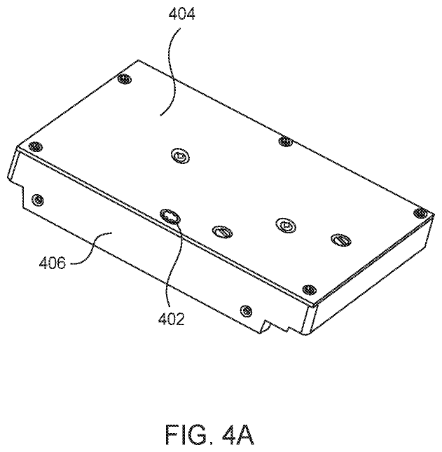

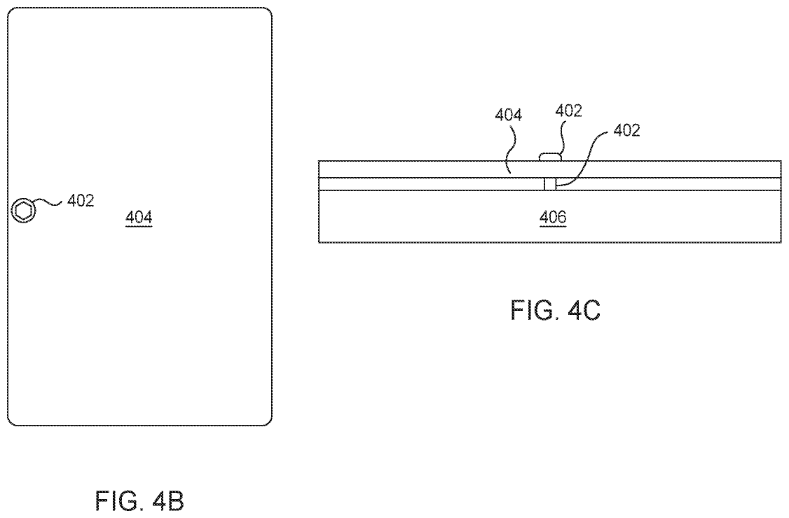

FIG. 4A through FIG. 7 are schematic illustrations of various data storage devices, such as an HDD or an SSD, with an added component (i.e., a sixth connector element 402, 502, 602, 702 of a plurality of connector elements in a sixth area disposed between the first corner area and the fourth corner area) to reduce RF interference according to various embodiments. Aspects of the various data storage devices of FIG. 4A through FIG. 7 may be similar to the data storage device illustrated in FIGS. 3A, 3B, and 3C. Though the storage device comprises a FIPG, the non-conductive adhesive does not reduce RF interference. As described in FIG. 2, RF interference shielding may reduce the leakage of radio waves or electromagnetic waves into the body of the storage device and reduce the interference effect on the magnetic head, in the case of HDD. Leakage of radio waves or electromagnetic waves may still occur through a gap formed by the coupling of a cover plate, such as the top plate 302 of FIGS. 3A and 3B, and a base plate, such as the base plate 304 of FIG. 3C.

A barrier of appropriate conductive material may be used to reduce leakage of radio waves into a space, and such material may include copper, which has an electrical conductivity of 5.96×10⁷ σ (S/m) at 20° C. or 68° F. The listed copper material is not intended to be limiting, but to provide an example of a possible embodiment, as materials that have an electrical conductivity comparable to copper or an electrical conductivity less than copper may be applicable as well. Furthermore, the conductive material may be a conductive compound (i.e., comprising two or more distinct elements). In various embodiments, the conductive material bridges the electrical connection of the cover plate and the base plate, which results in some shielding of the radio waves, the electromagnetic waves, and the like. In the following embodiments, the length, the position, and the number of conductive material elements illustrated are not intended to be limiting, but to provide an example of possible various embodiments.

In one embodiment, the span of the conductive material length is less than an inch. In another embodiment, the span of the conductive material length is greater than an inch, but less than the length of a slot between the top plate and the base plate. In yet another embodiment, the span of conductive material length is the length of the slot. In one embodiment, the conductive material comprises one or more deposits covering the long slot of the storage device. In one embodiment, the conductive material location is in the middle of the long slot of the storage device. In another embodiment, the conductive material location is unaligned with the middle of the long slot of the storage device. In one embodiment, the conductive material is a continuous deposit along the long slot of the storage device. In another embodiment, the conductive material is a non-continuous deposit along the long slot of the storage device.

FIGS. 4A, 4B, and 4C are schematic illustrations of data storage devices, such as an HDD, with an added component (i.e., a sixth connector element 402 of a plurality of connector elements in a sixth area disposed between the first corner area and the fourth corner area) to reduce RF interference according to various embodiments. FIG. 4A is a schematic isometric view illustration of a data storage device according to one embodiment. FIG. 4B is a simplified schematic top view illustration of FIG. 4A. FIG. 4C is a simplified schematic of a side view illustration of FIG. 4A.

In FIG. 4A, the data storage device comprises an example location for an added component (i.e., the sixth connector element 402), such as an electrically conductive screw. Unlike the opposite side, the example location for an added component does not currently have a screw, resulting in a long slot. The long slot may result in the decreased efficiency of RF interference mitigation and decreased throughput percentage. Furthermore, because the screws, such as the connector elements 306, 308, 310, 312, and 314 of FIGS. 3A-3C, of the cover plate 404 and the base plate 406 do not form a complete seal, the long slot on the side lacking a screw or connector element may allow more RF currents to leak into the enclosure than that of the opposite side comprising an electrically conductive middle screw (e.g., 310).

The added electrically conductive screw 402 in the middle of the long edge of FIG. 4B secures the cover plate 404 to the side wall of the base plate 406, as shown in FIG. 4C, effectively halving the long slot length of that side. By halving the long slot length (i.e., shortening the slot), the throughput percentage such as that shown in FIG. 2 may increase due to less RF frequency leaking into the body of the storage device. It is to be understood that while the embodiment shown halves the long slot, it is contemplated that the slot could be divided further such as into thirds, fourths, etc. and thus, the disclosure is not to be limited to simply halving the long slot length. The number of electrically conductive screws and the position of the electrically conductive screws illustrated in FIGS. 4A, 4B, and 4C are not intended to be limiting, but to provide an example of the various embodiments.

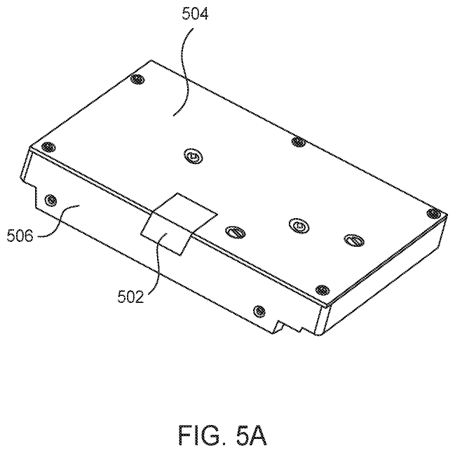

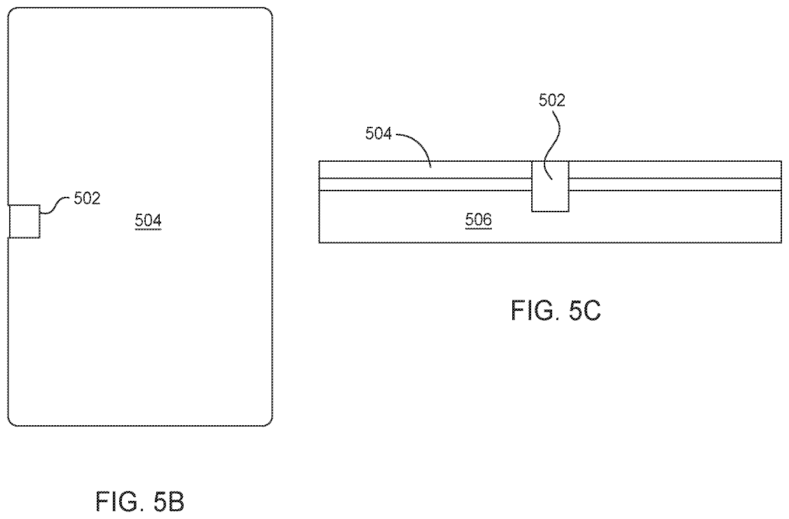

FIGS. 5A, 5B, and 5C are schematic illustrations of data storage devices, such as an HDD, with an added component (i.e., a sixth connector 502 element of a plurality of connector elements in a sixth area disposed between the first corner area and the fourth corner area) to reduce RF interference according to various embodiments. FIG. 5A is a schematic isometric view illustration of a data storage device according to one embodiment. FIG. 5B is a simplified schematic top view illustration of FIG. 5A. FIG. 5C is a simplified schematic of a side view illustration of FIG. 5A.

In FIGS. 5A, 5B, and 5C, the sixth connector element 502 is a stripe or film that is an external liquid application (i.e., covering outside the slot of the cover plate 504 and the base plate 506) of a conductive material, such as copper, adding an electrical connection covering a portion or all of the space of the long slot between to the cover plate 504 the base plate 506. The sixth connector 502 may be applied by inkjet, spray, or any other applicable manner of applying a liquid stripe or film to the storage device, such as applying a premade stripe or film to the storage device.

The liquid stripe or film becomes solid after applying heat and/or drying the liquid material. The liquid stripe or film provides a low resistance short after drying. The solid stripe or film has the same or similar conductivity as the liquid stripe or film. Similar to the electrically conductive screw of FIGS. 4A, 4B, and 4C, when applied to a portion of the slot length as shown in FIG. 5C, the electrically conductive stripe or film effectively halves the long slot length of that side. By halving the long slot length (i.e., shortening the slot), the throughput percentage such as that shown in FIG. 2 may increase due to less RF frequency leaking into the body of the storage device. It is to be understood that while the embodiment shown halves the long slot, it is contemplated that the slot could be divided further such as into thirds, fourths, etc. and thus, the disclosure is not to be limited to simply halving the long slot length. The number of electrically conductive stripes or films and the position of the electrically conductive stripes or films illustrated in FIGS. 5A, 5B, and 5C are not intended to be limiting, but to provide an example of the various embodiments.

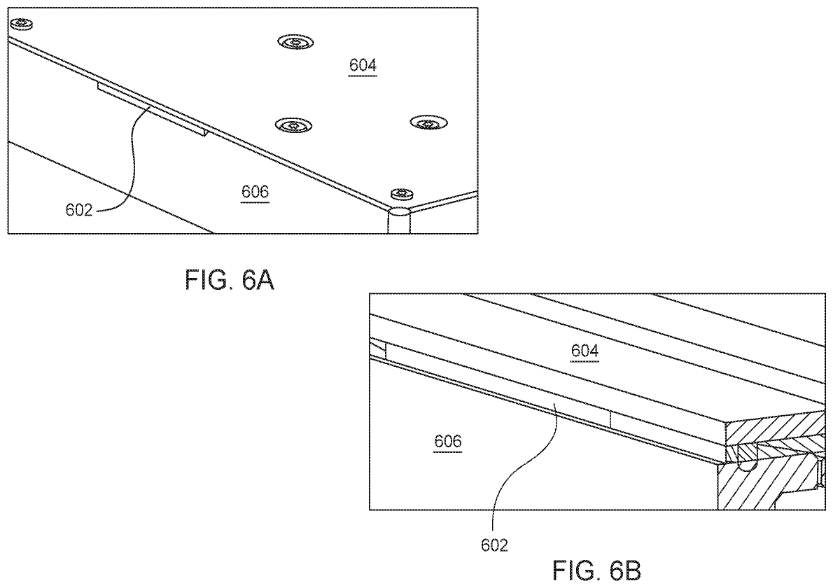

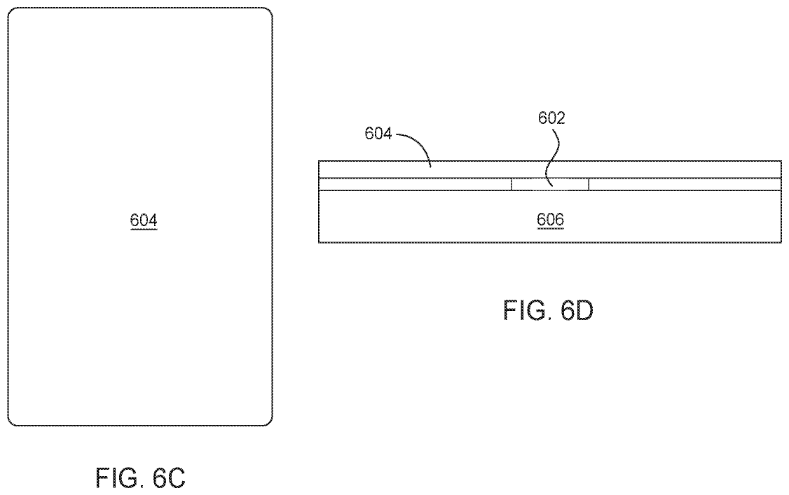

FIGS. 6A, 6B, 6C, and 6D are schematic illustrations of data storage devices, such as an HDD, with an added component (i.e., a sixth connector element 602 of a plurality of connector elements in a sixth area disposed between the first corner area and the fourth corner area) to reduce RF interference according to various embodiments. FIG. 6A is a schematic isometric view illustration of a data storage device according to one embodiment. FIG. 6B is an expanded schematic isometric view illustration of FIG. 6A. FIG. 6C is a simplified schematic top view illustration of FIG. 6A. FIG. 6D is a simplified schematic of a side view illustration of FIG. 6A.

In FIGS. 6A, 6B, 6C, and 6C, the sixth connector element 602 is a film that is an internal liquid application (i.e., located inside the slot formed by the cover plate 604 and the base plate 606) of a conductive material, such as copper, adding an electrical connection in the space of the long slot between to the cover plate 604 the base plate 606. The liquid film may be applied by inkjet, spray, or any other applicable manner of applying a liquid film to the storage device, such as applying an electrically conductive paste or gel.

The liquid film becomes solid after applying heat and/or drying the liquid material and may be flush with the cover plate 604 edge and the base plate 606 edge. The liquid film provides a low resistance short after drying. The solid film has the same or similar conductivity as the liquid film. Similar to the electrically conductive screw of FIGS. 4A, 4B, and 4C and the electrically conductive external stripe or film of FIGS. 5A, 5B, and 5C, when applied to a portion of the slot length as shown in FIG. 6D the electrically conductive film effectively halves the long slot length of that side. By halving the long slot length (i.e., shortening the slot), the throughput percentage such as that shown in FIG. 2 may increase due to less RF frequency leaking into the body of the storage device. The number of electrically conductive stripes or films and the position of the electrically conductive stripes or films illustrated in FIGS. 6A, 6B, 6C, and 6D are not intended to be limiting, but to provide an example of the various embodiments. It is to be understood that while the embodiment shown halves the long slot, it is contemplated that the slot could be divided further such as into thirds, fourths, etc. and thus, the disclosure is not to be limited to simply halving the long slot length.

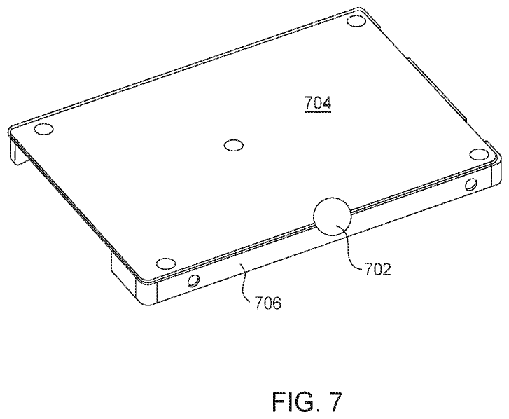

FIG. 7 is a schematic illustration of a data storage device, such as an SSD, with an added component (i.e., a sixth connector element 702 of a plurality of connector elements in a sixth area disposed between the first corner area and the fourth corner area) to reduce RF interference according to various embodiments. The internals of an SSD are enclosed by a metal enclosure formed by a cover plate 704, which may be similar to the cover plate 302 of FIGS. 3A, 3B, and 3C, and a base plate 706, which may be similar to the base plate 304 of FIGS. 3A, 3B, and 3C. The cover plate 704 is coupled to the base plate 706 through various connection elements described in FIGS. 3A, 3B, and 3C. The location of the sixth connector 702 that is shown in FIG. 7 is an example position of the application of the electrically conductive element, such as an electrically conductive screw of FIGS. 4A, 4B, and 4C or a stripe or film as applied in FIGS. 5A through 6D, in one embodiment. Alternatively, the position of the application of the electrically conductive element may be located on the opposite long edge of the cover plate 704, in another embodiment. In yet another embodiment, the position of the application of the electrically conductive element may be located on both long edges of the cover plate 704.

The application of the electrically conductive element in a location may provide a low resistance short. The electrically conductive element effectively halves the long slot length of that side. By halving the long slot length (i.e., shortening the slot), the data throughput percentage may increase due to less RF frequency leaking into the body of the storage device. The number of electrically conductive elements and the position of the electrically conductive elements illustrated in FIG. 7 is not intended to be limiting, but to provide an example of an embodiment. It is to be understood that while the embodiment shown halves the long slot, it is contemplated that the slot could be divided further such as into thirds, fourths, etc. and thus, the disclosure is not to be limited to simply halving the long slot length.

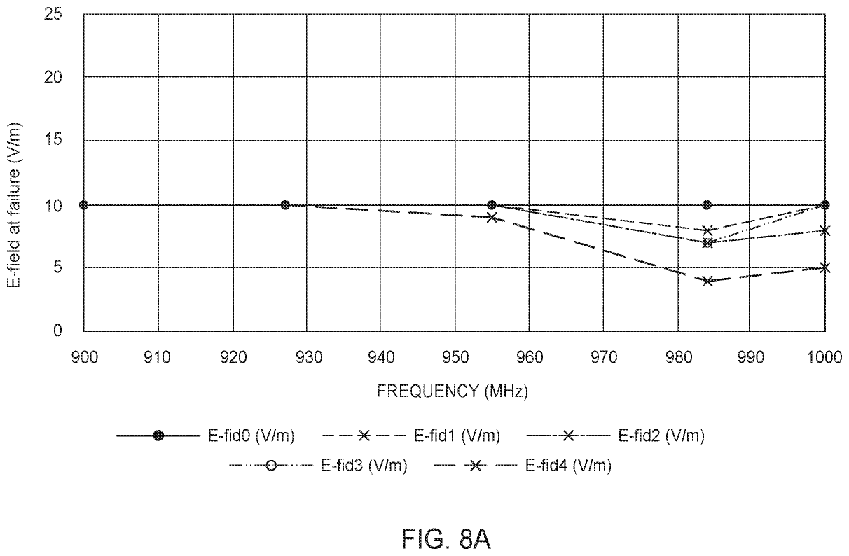

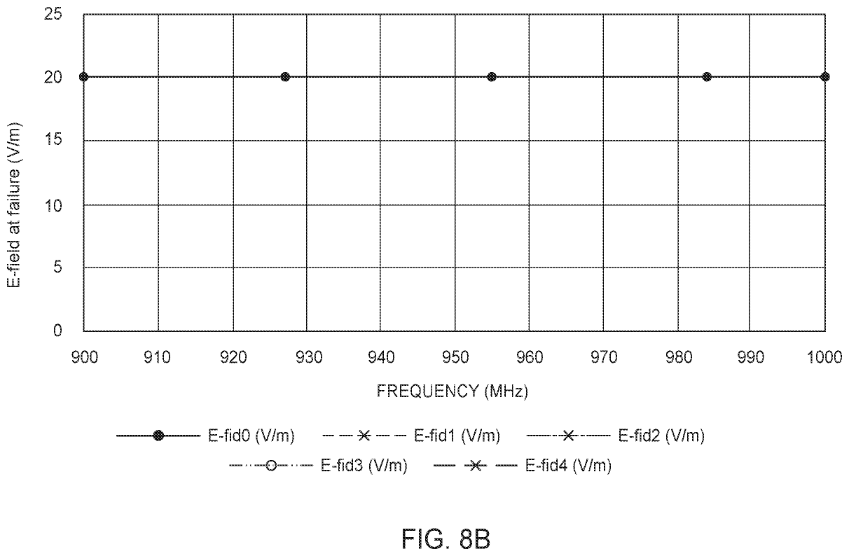

FIGS. 8A and 8B are graphs illustrating the benefits of reducing RF interference. FIG. 8A is a graph illustrating a baseline case, where the electrically conductive element, such as the electrically conductive elements described in FIGS. 3A-7, is not applied and the long slot on one side does not have the electrically conductive elements. For example, in FIG. 3A, there are only 5 connector elements, which would be a situation applicable to FIG. 8A. However, FIG. 8B is a graph illustrating the results of applying the electrically conductive element to the storage device. For example, in FIGS. 4A-4C, the added electrically conductive element is present, which would be a situation applicable to FIG. 8B. In both FIGS. 8A and 8B, the frequency (MHz) that the drive is exposed to is on the x-axis and the electrical field strength at failure (V/m) is on the y-axis.

If the quality assurance threshold is 90% (i.e., the electrical field strength must be greater than 90% of the generated electrical field when a frequency is applied), multiple magnetic heads, such as the magnetic head 121 of FIG. 1, of FIG. 8A do not meet the minimum threshold (i.e., the electrical field strength of multiple magnetic heads are below 9 V/m (10 V/m*0.90=9 V/m)). However, by applying the electrically conductive element (or elements) to the storage device, such as in FIG. 8B, the magnetic heads 121 are able to maintain a constant higher electrical field strength (i.e., 20 V/m) as the frequency applied is increased. Furthermore, the decrease in electrical field strength may be minimal when higher frequencies of radio waves, electromagnetic waves, or the like are applied and may allow for more optimal drive operation (i.e., less bit errors and constant data throughput).

By using a conductive material to seal the top plate to the base of a data storage device such as an HDD or SSD, RF signal cannot penetrate into the drive and cause RF interference. As such, data errors are minimized and data throughput is maintained at a high level.

In one embodiment, a data storage device comprises: a base body; a top plate; and a plurality of connector elements, wherein: a first connector element of the plurality of connector elements couples a first corner area of the top plate to a corresponding first corner area of the base body; a second connector element of the plurality of connector elements couples a second corner area of the top plate to a corresponding second corner area of the base body; a third connector element of the plurality of connector elements couples a third corner area of the top plate to a corresponding third corner area of the base body; a fourth connector element of the plurality of connector elements couples a fourth corner area of the top plate to a corresponding fourth corner area of the base body; a fifth connector element of the plurality of connector elements couples a fifth area of the top plate to a corresponding fifth area of the base body, wherein the fifth area is disposed between the second area and the third area; and a sixth connector element of the plurality of connector elements couples a sixth area of the top plate to a corresponding sixth area of the base body, wherein the sixth area is disposed between the first area and the fourth area, wherein at least one of the fifth connector element and the sixth connector element is electrically conductive. The data storage device is a hard disk drive. The data storage device is a solid state drive. The sixth connector is an electrically conductive screw. The sixth connector is an electrically conductive material coupled between the top plate and the base body. The sixth connector is an electrically conductive material that is coupled to a top surface of the top plate and a sidewall of the base body. The fifth connector is aligned with the sixth connector, and the sixth connector is aligned with the first connector and the fourth connector. At least one connector of the plurality of connectors is different from at least one other connector of the plurality of connectors.

In another embodiment, a data storage device comprises: a base body having a first base body edge, a second base body edge, a third base body edge and a fourth base body edge, wherein the first base body edge and the third base body edge are parallel and of equal length, wherein the second base body edge and the fourth base body edge are parallel and of equal length, and wherein the first base body edge is shorter than the second base body edge; a top plate having a first top plate edge, a second top plate edge, a third top plate edge and a fourth top plate edge, wherein the first top plate edge and the third top plate edge are parallel and of equal length, wherein the second top plate edge and the fourth top plate edge are parallel and of equal length, and wherein the first top plate edge is shorter than the second top plate edge; and a plurality of connector elements, wherein: a first connector element of the plurality of connector elements couples the second base body edge to the second top plate edge; and a second connector element of the plurality of connector elements couples the fourth base body edge to the fourth top plate edge, wherein at least one of the first connector element and the second connector element is electrically conductive. The first connector element extends through the second top plate edge and into the second base body edge. The first connector element extends along a top surface of the second top plate edge and along a sidewall surface of the second base body edge. The first connector element is disposed between the second top plate edge and the second base body edge. The first connector element is in contact with both the second top plate edge and the second base body edge. The first connector element comprises a material having an electrical conductivity that is less than an electrical conductivity of copper. The first connector element is a screw and the second connector element is not a screw. The second base body edge is spaced from the second top plate edge at a location spaced from the first connector element of the plurality of connector. The fourth base body edge is spaced from the fourth top plate edge at a location spaced from the second connector element of the plurality of connector. The first connector element and the second connector element are different.

In another embodiment, a data storage device comprises: a base body; a top plate; and means to reduce radio frequency interference, wherein the means to reduce radio frequency interference is disposed between at locations disposed away from corner areas of the base body and the top plate. The data storage device is a hard disk drive or a solid state drive

While the foregoing is directed to embodiments of the present disclosure, other and further embodiments of the disclosure may be devised without departing from the basic scope thereof, and the scope thereof is determined by the claims that follow.

1. A data storage device, comprising:
a base body;
a top plate having an inward facing surface and an outward facing surface, wherein the outward facing surface is substantially planar;
a non-conductive adhesive disposed between the base body and the top plate; and
a plurality of connector elements, the plurality of connector elements being substantially flush with the outward facing surface, wherein:
a first connector element of the plurality of connector elements couples a first corner area of the top plate to a corresponding first corner area of the base body;
a second connector element of the plurality of connector elements couples a second corner area of the top plate to a corresponding second corner area of the base body;
a third connector element of the plurality of connector elements couples a third corner area of the top plate to a corresponding third corner area of the base body;
a fourth connector element of the plurality of connector elements couples a fourth corner area of the top plate to a corresponding fourth corner area of the base body;
a fifth connector element of the plurality of connector elements couples a fifth area of the top plate to a corresponding fifth area of the base body, wherein the fifth area is disposed between the second area and the third area; and
a sixth connector element of the plurality of connector elements couples a sixth area of the top plate to a corresponding sixth area of the base body, wherein the sixth area is disposed between the first area and the fourth area, wherein at least one of the fifth connector element and the sixth connector element is electrically conductive.

2. The data storage device of claim 1, wherein the data storage device is a hard disk drive.

3. The data storage device of claim 1, wherein the data storage device is a solid state drive.

4. The data storage device of claim 1, wherein the sixth connector element comprises an electrically conductive screw.

5. The data storage device of claim 1, wherein the sixth connector element comprises an electrically conductive material coupled between the top plate and the base body.

6. The data storage device of claim 1, wherein the sixth connector element comprises an electrically conductive material that is coupled to a top surface of the top plate and a sidewall of the base body.

7. The data storage device of claim 1, wherein the fifth connector element is aligned with the sixth connector element, and the sixth connector element is aligned with the first connector element and the fourth connector element.

8. The data storage device of claim 1, wherein at least one connector element of the plurality of connector elements is different from at least one other connector element of the plurality of connector elements.

9. A data storage device, comprising:
a base body having a first base body edge, a second base body edge, a third base body edge and a fourth base body edge, wherein the first base body edge and the third base body edge are parallel and of equal length, wherein the second base body edge and the fourth base body edge are parallel and of equal length, and wherein the first base body edge is shorter than the second base body edge;
a top plate having a substantially planar external surface, a first top plate edge, a second top plate edge, a third top plate edge and a fourth top plate edge, the first, second, third, and fourth top plate edges being coupled to the substantially planar external surface, wherein the first top plate edge and the third top plate edge are parallel and of equal length, wherein the second top plate edge and the fourth top plate edge are parallel and of equal length, and wherein the first top plate edge is shorter than the second top plate edge;
a non-conductive adhesive disposed between the first base body edge and the first top plate edge, between the second base body edge and the second top plate edge, between the third base body edge and the third top plate edge, and between the fourth base body edge and the fourth top plate edge; and
a plurality of connector elements, the plurality of connector elements being substantially flush with the outward facing surface, wherein:
a first connector element of the plurality of connector elements couples the second base body edge to the second top plate edge; and
a second connector element of the plurality of connector elements couples the fourth base body edge to the fourth top plate edge, wherein at least one of the first connector element and the second connector element is electrically conductive.

10. The data storage device of claim 9, wherein the first connector element extends through the second top plate edge and into the second base body edge.

11. The data storage device of claim 9, wherein the first connector element extends along a top surface of the second top plate edge and along a sidewall surface of the second base body edge.

12. The data storage device of claim 9, wherein the first connector element is disposed between the second top plate edge and the second base body edge.

13. The data storage device of claim 12, wherein the first connector element is in contact with both the second top plate edge and the second base body edge.

14. The data storage device of claim 9, wherein the first connector element comprises a material having an electrical conductivity that is less than an electrical conductivity of copper.

15. The data storage device of claim 9, wherein the first connector element is a screw and the second connector element is not a screw.

16. The data storage device of claim 9, wherein the second base body edge is spaced from the second top plate edge at a location spaced from the first connector element of the plurality of connector elements.

17. The data storage device of claim 16, wherein the fourth base body edge is spaced from the fourth top plate edge at a location spaced from the second connector element of the plurality of connector elements.

18. The data storage device of claim 17, wherein the first connector element and the second connector element are different.

19. A data storage device, comprising:
a base body having a first base body edge, a second base body edge, a third base body edge and a fourth base body edge, wherein the first base body edge and the third base body edge are parallel and of equal length, wherein the second base body edge and the fourth base body edge are parallel and of equal length, and wherein the first base body edge is shorter than the second base body edge;
a top plate having a substantially planar external surface, a first top plate edge, a second top plate edge, a third top plate edge, and a fourth top plate edge, the first, second, third, and fourth top plate edges being coupled to the substantially planar external surface, wherein the first top plate edge and the third top plate edge are parallel and of equal length, wherein the second top plate edge and the fourth top plate edge are parallel and of equal length, wherein the first top plate edge is shorter than the second top plate edge, and wherein the first base body edge is substantially flush with the first top plate edge, the second base body edge is substantially flush with the second top plate edge, the third base body edge is substantially flush with the third top plate edge, and the fourth base body edge is substantially flush with the fourth top plate edge;
a non-conductive adhesive disposed between the first base body edge and the first top plate edge, between the second base body edge and the second top plate edge, between the third base body edge and the third top plate edge, and between the fourth base body edge and the fourth top plate edge; and
means to reduce radio frequency interference, wherein the means to reduce radio frequency interference is disposed between the base body and the top plate, at locations disposed away from corner areas of the base body and the top plate.

20. The data storage device of claim 19, wherein the data storage device is a hard disk drive or a solid state drive.

21. The data storage device of claim 1, wherein the sixth connector element is a continuous deposit of an electrically conductive material disposed along a perimeter of the base body such that the sixth connector element is disposed between the base body and the top plate.
